(19) United States
(12) Patent Application Publication
(10) Pub. No.: US 2008/0132062 A1
(43) Pub. Date: Jun. 5, 2008

(54) METHOD OF MANUFACTURING SEMICONDUCTOR DEVICE

(75) Inventor: Akira FURUYA, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 11/950,464

(22) Filed: Dec. 5, 2007

(30) Foreign Application Priority Data
Dec. 5, 2006 (JP) 2006-327866

(51) Int. Cl. H01L 21/44

(52) U.S. Cl. 438/653; 257/E21.476

(57) ABSTRACT

To obtain a copper film having satisfactory electrical characteristics with a simple structure, there is provided a method of manufacturing a semiconductor device including the step of forming on a semiconductor substrate a barrier metal film to be a seed film which functions as a cathode when a copper film is formed by electrolytic plating (S10), the step of immersing the barrier metal film in a plating solution containing copper ion in a plating bath for a predetermined length of time with the barrier metal film and an anode being substantially at the same potential (S20), and the step of, after the barrier metal film is immersed in the copper sulfate plating solution for the predetermined length of time, applying voltage between the barrier metal film and the anode with the barrier metal film being kept immersed in the plating solution to form a copper film on the barrier metal film (S30).

### BACKGROUND OF THE INVENTION

1. Field of the Invention

The present invention relates to a method of manufacturing a semiconductor device.

2. Description of Related Art

In recent semiconductor devices, delay in signal transmission on interconnects may sometimes determine operation speed of LSI circuits. Delay constant of signal transmission on interconnects is expressed by a product of interconnect resistance and parasitic capacitance. In order to reduce the interconnect resistance so as to enhance the operation speed of the LSI circuits, copper having a small resistivity has been becoming popular as an interconnect material.

Copper multilayer interconnect may be formed by the damascene process. The damascene process generally includes a step of depositing an insulating film such as an interlayer insulating film, a step of forming an opening such as a via hole or a trench, a step of depositing a barrier metal film, a step of depositing a copper thin film to be a seed film, a step of filling the opening by depositing a copper film with the seed film being used as a cathode in electrolytic plating, a step of removing the copper film and the barrier metal film, which are exposed to the outside of the opening, by chemical mechanical polishing (CMP), and a step of depositing a barrier insulating film. By repeating these steps, a multilayer interconnect structure is formed.

Conventionally, when a copper film is formed on a semiconductor wafer by electrolytic plating, the semiconductor wafer is immersed in a plating solution with the semiconductor wafer being used as a cathode and with voltage being applied between the semiconductor wafer and an anode. For example, Japanese Patent Laid-open Application No. 2006-40908 describes that “in forming a Cu film using electrolytic plating, for fear that the seed film might be dissolved at the start of the plating step, the semiconductor wafer is immersed in a plating solution with voltage being applied between the wafer and an anode.

On the other hand, in recent years, a technique to use a barrier metal film instead of a copper thin film as the seed film has been developed (Japanese Patent Laid-open Application No. 2006-120870 and S. K. Cho et al., “Damascene Cu electrodeposition on metal organic chemical vapor deposition-grown Ru thin film barrier”, J. Vac. Sol. Technol. B22 (6), November/December 2004, pp 2649-2653). Japanese Patent Laid-open Application No. 2006-120870 describes a process of forming on a substrate, palladium, rhodium, or ruthenium as a conductive film which is insoluble in an electrolytic plating solution for forming a interconnect material film and forming the interconnect material film on the conductive film by electrolytic plating with the conductive film being used as a seed film. It should be noted that, in the document, also, the plating solution is supplied to the inside of an electrode portion with plating voltage being applied between an anode and a cathode.

When there is a void in copper interconnect, there arises problems such as an increase in resistance of the copper interconnect, and decreases in reliability and yield of products. Therefore, when copper interconnect is formed by plating, it is important to prevent a void from being formed. In plating, the copper film grows faster near the top of the opening and at the bottom of the opening. If the copper film at the bottom reaches the top of the opening before the top of the opening is closed, copper interconnect without a void can be formed. Therefore, it is preferable that the formed seed film is as thin as possible to enlarge the width of the opening. By using a barrier metal film as the seed film, the width of the opening can be made large to prevent a void from being formed.

Conventionally, when a substrate is immersed in a plating solution, the substrate is sometimes immersed obliquely in order to remove gases such as air and to obtain a uniform plating film. However, the inventor of the present invention found that, when a barrier metal film made of ruthenium, palladium, rhodium, or the like is used as a cathode electrode, if a substrate is immersed obliquely in a plating solution with voltage being applied between the barrier metal film and an anode in a conventional way, abnormal growth due to current concentration is caused in the vicinity of a portion of the substrate which is in contact with the plating solution. The reason is thought to be the higher electrical current of the electrolytic plating which is set because, when a barrier metal film is used as a seed film, compared with a case where a copper thin film is used as a seed film, a growth nucleus of copper is hard to create in plating.

Further, when a barrier metal film is used as a seed film in electrolytic plating, conventionally, after a conductive film (barrier metal film) to be a seed film is formed and before plating in a plating solution is carried out, pretreatment of the surface of the conductive film is necessary. For example, Japanese Patent Laid-open Application No. 2006-120870 discloses that, in order to improve the uniformity of a plating base (conductive film) in advance, for example, the wettability is made uniform by washing with water, by treatment with a surface-active agent, or the like, and an oxide film formed on the surface is removed or reduced by treatment with a chemical solution, plasma treatment, or the like. S. K. Cho et al., “Damascene Cu electrodeposition on metal organic chemical vapor deposition-grown Ru thin film barrier”, J. Vac. Sci. Technol. B22 (6), November/December 2004, pp 2649-2653 discloses that, in order to form a Cu film satisfactorily, a substrate is immersed in a solution containing PdCl₂, HCl, HF, or the like before plating. Such pretreatment is carried out in a bath or an apparatus that is different from a plating bath containing the plating solution, which makes the plating apparatus larger or more complicated and decreases the throughput at the plating step.

### SUMMARY

According to the present invention, there is provided a method of manufacturing a semiconductor device including:

immersing a substrate with a barrier metal film in a plating solution containing copper ion in a state where the barrier metal film and an anode are substantially at the same potential; and

applying a voltage between the barrier metal film and the anode to form a copper film over the barrier metal film.

Further, according to the present invention, there is provided a method of manufacturing a semiconductor device including:

forming an insulating film over a substrate;

forming an opening in the insulating film;

forming a barrier metal film over the insulating film and a surface of the opening;

immersing the substrate in a plating solution containing copper ion in a state where the barrier metal film and an anode are substantially at the same potential; and

applying a voltage between the barrier metal film and the anode to form a copper film over the barrier metal film so as to fill the opening.

According to the present invention, because, in immersion, no voltage is applied between the barrier metal film and the anode and the barrier metal film and the anode are substantially at the same potential, abnormal growth can be prevented. Further, because the semiconductor substrate is immersed in the plating solution for the predetermined length of time with the barrier metal film and the anode being substantially at the same potential, gases such as air are removed during the predetermined length of time, and thus, a uniform plating film can be obtained even if the substrate is not immersed obliquely.

Further, the inventor of the present invention found that, when a barrier metal film is used as a seed film in electrolytic plating, by devising a treatment process, a satisfactory copper film can be formed by electrolytic plating without preparing an additional apparatus for pretreatment.

In this way, the present inventor of the present invention found that, when a barrier metal film is used as a seed film in electrolytic plating, by immersing the barrier metal film in a plating solution for a predetermined length of time with the barrier metal film and the anode being substantially at the same potential, an oxide film is removed in a similar way to a conventional case where an additional bath or apparatus is used. In other words, according to the present invention, a plating bath and a plating solution for forming a copper film can also be used as a pretreatment bath and a pretreatment solution for the barrier metal film. This can make the structure of the plating apparatus simpler, and makes it possible to obtain a copper film having satisfactory electrical characteristics while the throughput in plating is increased. Here, the state where the barrier metal film and the anode are substantially at the same potential may be a state where no voltage is applied to the barrier metal film and the anode or may be a state where voltage is applied to the barrier metal film such that the potential of the barrier metal film is the same as that of the anode. The state where the barrier metal film and the anode are substantially at the same potential may be a state where the substantial potential difference between barrier metal film and the anode does not cause film formation by plating on the barrier metal film. Depending on the structure of the apparatus, the potential difference varies, but the difference may be, for example, 0.5 V or lower.

According to the present invention, a copper film having satisfactory electrical characteristics with a simple structure can be obtained.

### BRIEF DESCRIPTION OF THE DRAWINGS

In the accompanying drawings:

FIG. 1 is a flow chart illustrating a process of forming a copper film by electrolytic plating according to an embodiment of the present invention;

FIGS. 2A to 2D schematically illustrate the process illustrated in FIG. 1; and

FIGS. 3A to 3C are sectional views illustrating a process of manufacturing a semiconductor device including copper interconnect according to the embodiment of the present invention.

### DETAILED DESCRIPTION OF THE PREFERRED EMBODIMENTS

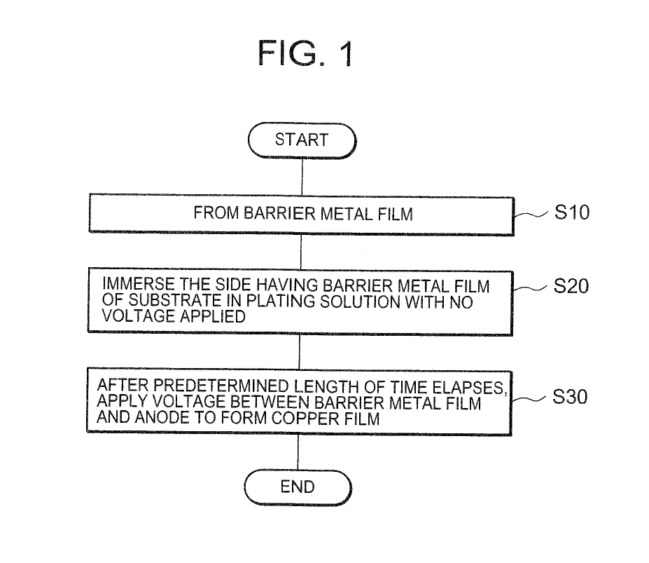

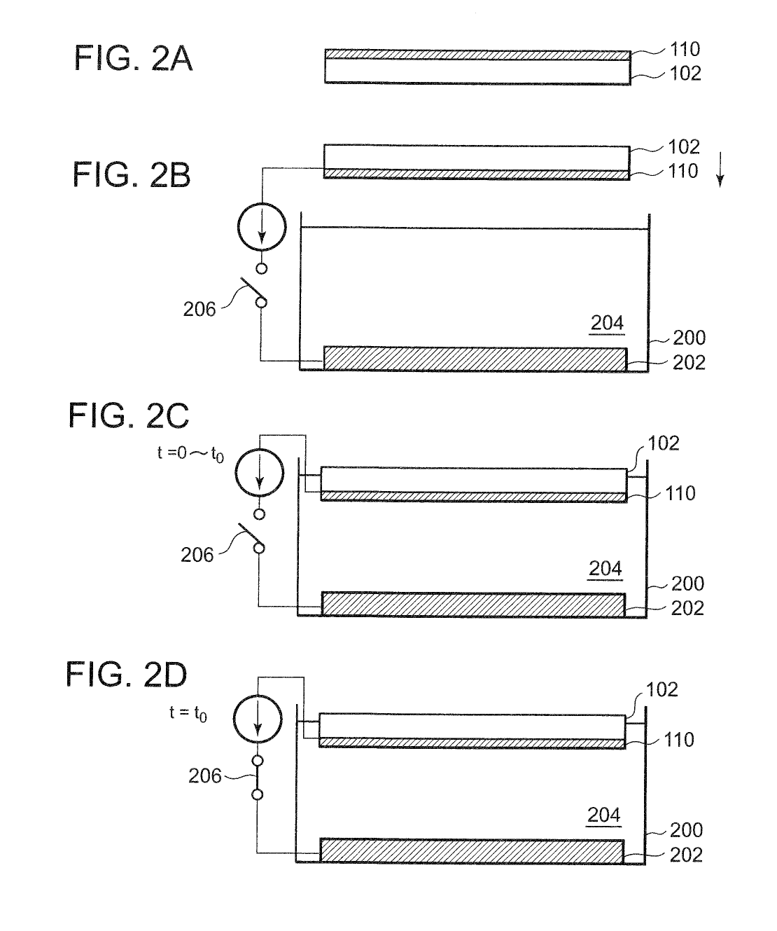

FIG. 1 is a flow chart illustrating a process of forming a copper film on a substrate by electrolytic plating according to this embodiment. FIG. 2 schematically illustrates the process.

First, a barrier metal film 110 is formed over a semiconductor substrate 102 which is, for example, a silicon substrate (S10, FIG. 2A). The barrier metal film 110 is to be a seed film which functions as a cathode when a copper film is formed by electrolytic plating. The barrier metal film 110 is insoluble in a plating solution 204. The barrier metal film may be formed of, for example, Ru (ruthenium), Pd (palladium), or Rh (rhodium).

Then, the semiconductor substrate 102 is immersed in the plating solution 204 in a plating bath 200 with a side having the barrier metal film 110 formed thereon down. Here, the semiconductor substrate 102 may be put in the plating bath 200 such that the surface of the semiconductor substrate 102 (the side having the barrier metal film 110 formed thereon) is substantially in parallel with a top surface of the plating solution 204 in the plating bath 200. Further, the semiconductor substrate 102 is put in the plating bath 200 with a switch 206 between a power supply line connected to the barrier metal film 110 and a power supply line connected to an anode 202 being turned off and with no voltage being applied between the barrier metal film 110 and the anode 202. With this state being maintained, the barrier metal film 110 is immersed in the plating solution 204 for a predetermined length of time to (S20, FIG. 2B and FIG. 2C). The plating solution 204 is a solution containing copper ions, and may be, for example, an aqueous solution of copper sulfate. Further, a leveler, an accelerator, and a suppressor may be added to the plating solution 204 as additives.

The predetermined length of time to may be 0.5 seconds or longer. This can satisfactorily remove an oxide film and the like formed on the barrier metal film 110. Because the barrier metal film 110 is insoluble in the plating solution 204, reduction in the film thickness due to dissolution of the barrier metal film 110 is not caused. Further, in order to increase the throughput, the predetermined length of time to may be 10 seconds or shorter. The anode 202 may be a dissoluble copper anode or may be an insoluble anode, and is not specifically limited.

After the barrier metal film 110 is immersed in the plating solution 204 for the predetermined length of time to, the switch 206 is turned on, and, with the barrier metal film 110 immersed in the plating solution 204, voltage is applied between the barrier metal film 110 and the anode 202 (S30, FIG. 2(d)). This forms a copper film on the barrier metal film 110.

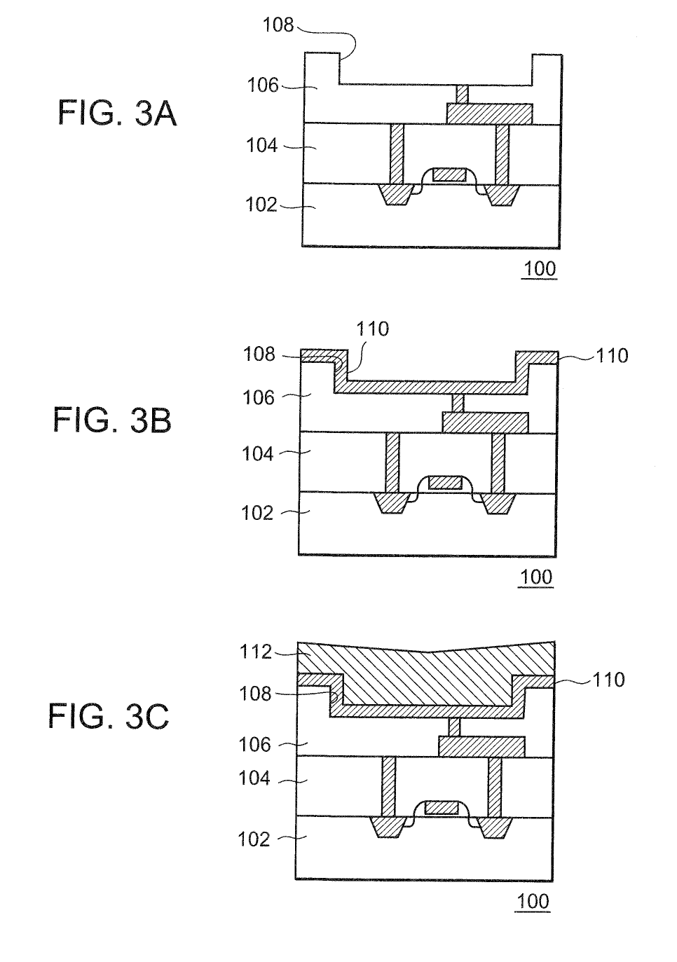

Next, a process of manufacturing a semiconductor device 100 including copper interconnect according to this embodiment is described with reference to FIG. 3. Hereinafter, description is made also with reference to FIG. 2.

A transistor and the like are formed on the semiconductor substrate 102. Further, an interlayer insulating film 104 and an interlayer insulating film 106 are formed in this order over the semiconductor substrate 102. Interconnect and vias are formed in the interlayer insulating films 104 and 106.

In the semiconductor device 100 structured in this way, first, an opening 108 is formed in the interlayer insulating film 106 (FIG. 3A). Although, here, the opening 108 is a trench for interconnect, the opening 108 may be a via hole or the structure may be a dual damascene structure in which the opening 108 is formed of a trench for interconnect and a via hole formed thereunder.

The opening 108 is filled in with a interconnect material as follows. First, the barrier metal film 110 is formed over the whole surface of the interlayer insulating film 106. This forms the barrier metal film 110 on a bottom surface and side surfaces of the opening 108 (FIG. 3B). In this embodiment, the barrier metal film 110 may be formed of Ru. By using Ru as the barrier metal film 110, adherence between the barrier metal film 110 and the copper film can be made satisfactory. The barrier metal film 110 may be formed by, for example, CVD or sputtering. The thickness of the barrier metal film 110 may be, for example, on the order of 1-5 nm.

After that, without particular pretreatment, the barrier metal film 110 of the semiconductor device 100 is immersed in the plating solution 204 in the plating bath 200. Here, as described above, the barrier metal film 110 is immersed for the predetermined length of time to with no voltage being applied between the barrier metal film 110 and the anode 202, that is, with the barrier metal film 110 and the anode 202 being substantially at the same potential. Accordingly, an oxide film and the like formed on the barrier metal film 110 are removed. Then, after the predetermined length of time to elapses, voltage is applied between the barrier metal film 110 and the anode 202. Here, negative current on the order of 10-150 A/m² is applied to the barrier metal film 110. As a result, a copper film 112 is formed on the barrier metal film 110, and the opening 108 is filled in with the copper film 112 (FIG. 3C).

After that, the semiconductor device 100 is taken out of the plating bath 200, and the copper film 112 and the barrier metal film 110, which are exposed to the outside of the opening 108, are removed by CMP. In this way, copper interconnect is formed.

In this embodiment, by immersing the barrier metal film 110 in the plating solution 204 for the predetermined length of time with no voltage being applied to the barrier metal film 110, the oxide film is removed in a similar way to a conventional case where an additional bath or apparatus is used. In other words, in this embodiment, the plating bath 200 and the plating solution 204 for forming the copper film is also used as a pretreatment bath and a pretreatment solution for the barrier metal film 110. This can make the structure of the plating apparatus simpler, and can increase the throughput in plating.

### EXAMPLE

Similarly to the embodiment described with reference to FIG. 3, the opening 108 formed in the interlayer insulating film 106 was filled in with a copper film by electrolytic plating. Here, the size of the opening 108 was 0.10 μm and Ru was used for the barrier metal film 110 (film thickness: about 5 nm). A copper sulfate plating solution was used as the plating solution 204. The plating was carried out under the following conditions.

### Example 1

The barrier metal film 110 was immersed in the plating solution 204 with no voltage being applied between the barrier metal film 110 and the anode 202 in immersion. After one second elapsed with this state being maintained, voltage was applied between the barrier metal film 110 and the anode 202 (negative current of 100 A/m² was applied to the barrier metal film 110) to fill in the opening 108 with a copper film.

### Example 2

### Comparative Example

The barrier metal film 110 was immersed in the plating solution 204 with voltage being applied between the barrier metal film 110 and the anode 202 in immersion (negative current of 100 A/m² was applied to the barrier metal film 110), and, with this state maintained, the opening 108 was filled in with a copper film.

The manufactured copper interconnect was observed with TEM. While no void was observed in Example 1, voids were observed in Example 2.

Although the embodiment of the present invention has been described above with reference to the drawings, this is merely exemplary and other various structures can be adopted.

What is claimed is:

1. A method of manufacturing a semiconductor device comprising:
immersing a substrate with a barrier metal film in a plating solution containing copper ion in a state where said barrier metal film and an anode are substantially at the same potential; and
applying a voltage between said barrier metal film and said anode to form a copper film over said barrier metal film.

2. The method of manufacturing a semiconductor device according to claim 1, wherein said barrier metal film is insoluble in said plating solution.

3. The method of manufacturing a semiconductor device according to claim 1, wherein said barrier metal film is formed at least one of ruthenium, palladium, and rhodium.

4. The method of manufacturing a semiconductor device according to claim 1, wherein said plating solution comprises an aqueous solution of copper sulfate.

5. The method of manufacturing a semiconductor device according to claim 1, wherein said state is such that no voltage is applied to said barrier metal film and said anode.

6. The method of manufacturing a semiconductor device according to claim 1, wherein said state is such that a voltage is applied to said barrier metal film such that a potential of said barrier metal film is the same as that of said anode.

7. The method of manufacturing a semiconductor device according to claim 1, wherein said state is such that a potential difference between said barrier metal film and said anode causes no film formation on said barrier metal film.

8. The method of manufacturing a semiconductor device according to claim 7, wherein said potential difference is 0.5 V or lower.

9. A method of manufacturing a semiconductor device comprising:
forming an insulating film over a substrate;
forming an opening in said insulating film;
forming a barrier metal film over said insulating film and a surface of said opening;
immersing said substrate in a plating solution containing copper ion in a state where said barrier metal film and an anode are substantially at the same potential; and
applying a voltage between said barrier metal film and said anode to form a copper film over said barrier metal film so as to fill said opening.

10. The method of manufacturing a semiconductor device according to claim 9, said opening is at least one of a trench and a via hole.

11. The method of manufacturing a semiconductor device according to claim 9, wherein said barrier metal film is insoluble in said plating solution.

12. The method of manufacturing a semiconductor device according to claim 9, wherein said barrier metal film is formed at least one of ruthenium, palladium, and rhodium.

13. The method of manufacturing a semiconductor device according to claim 9, wherein said plating solution comprises an aqueous solution of copper sulfate.

14. The method of manufacturing a semiconductor device according to claim 9, wherein said state is such that no voltage is applied to said barrier metal film and said anode.

15. The method of manufacturing a semiconductor device according to claim 9, wherein said state is such that a voltage is applied to said barrier metal film such that a potential of said barrier metal film is the same as that of said anode.

16. The method of manufacturing a semiconductor device according to claim 9, wherein said state is such that a potential difference between said barrier metal film and said anode causes no film formation on said barrier metal film.

17. The method of manufacturing a semiconductor device according to claim 16, wherein said potential difference is 0.5 V or lower.

18. The method of manufacturing a semiconductor device according to claim 9, further comprising:
after forming said copper film, removing said copper film and said barrier metal film which are exposed to an outside of said opening by chemical mechanical polishing (CMP).
